(19) United States
(12) Patent Application Publication
(10) Pub. No.: US 2025/0210413 A1
(43) Pub. Date: Jun. 26, 2025

(54) ELECTRONIC DEVICE AND MANUFACTURING METHOD THEREOF

(71) Applicant: Taiwan Semiconductor Manufacturing Company, Ltd., Hsinchu (TW)

(72) Inventors: Ting-Ya LO, Hsinchu (TW); Cheng-Chin Lee, Taipei City (TW); Shao-Kuan Lee, Kaohsiung City (TW); Hsin-Yen Huang, New Taipei City (TW); Hsiao-Kang Chang, Hsinchu City (TW)

(73) Assignee: Taiwan Semiconductor Manufacturing Company, Ltd., Hsinchu (TW)

(21) Appl. No.: 18/396,662

(22) Filed: Dec. 26, 2023

(51) Int. Cl. H01L 21/768; H01L 23/528; H01L 23/532

(52) U.S. Cl. CPC H01L 21/7682; H01L 21/76832; H01L 21/76885; H01L 23/5283; H01L 23/53295

(57) ABSTRACT

An electronic device including a first interconnect, a second interconnect, and an insulating layer is provided. A lower portion of the first interconnect is laterally spaced apart from a lower portion of the second interconnect by an air gap. The insulating layer is disposed laterally between an upper portion of the first interconnect and an upper portion of the second interconnect.

### BACKGROUND

The semiconductor integrated circuit (IC) industry has experienced a fast-paced growth. Technological advances in IC materials and design have produced generations of ICs where each generation has smaller and more complex circuits than the previous generation. The heat generated when the IC is operating may affect the quality. The quality of the IC may be improved through material selection or structural adjustments.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1K illustrate various cross-sectional views of some embodiments of a method of forming an electronic device.

FIG. 1L illustrates a various top view of some embodiments of an electronic device.

FIGS. 2A-2E illustrate various cross-sectional views of some embodiments of a method of forming an electronic device.

FIGS. 3A-3C illustrate various cross-sectional views of some embodiments of a method of forming an electronic device.

FIG. 4 illustrates an exemplary cross-sectional view of an electronic device.

FIG. 5 illustrates a flow diagram of some embodiments of a method of forming an electronic device.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

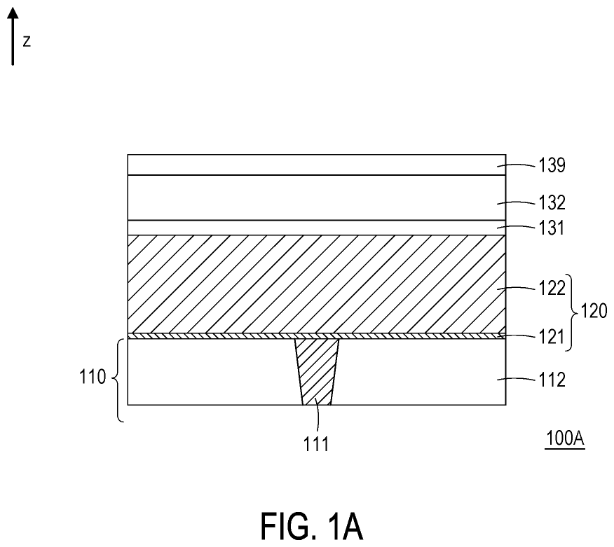

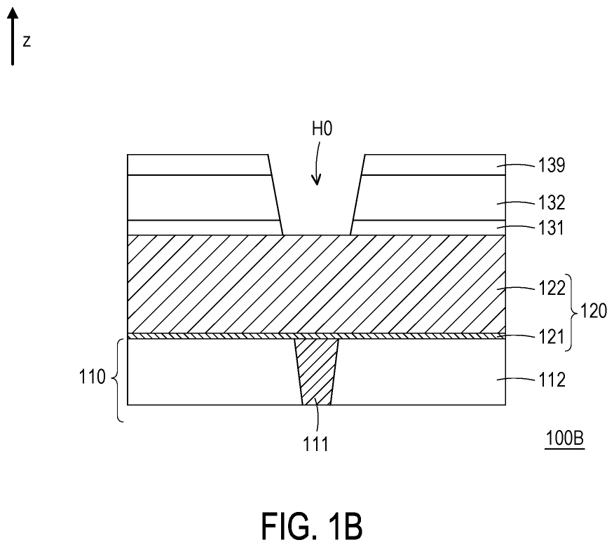

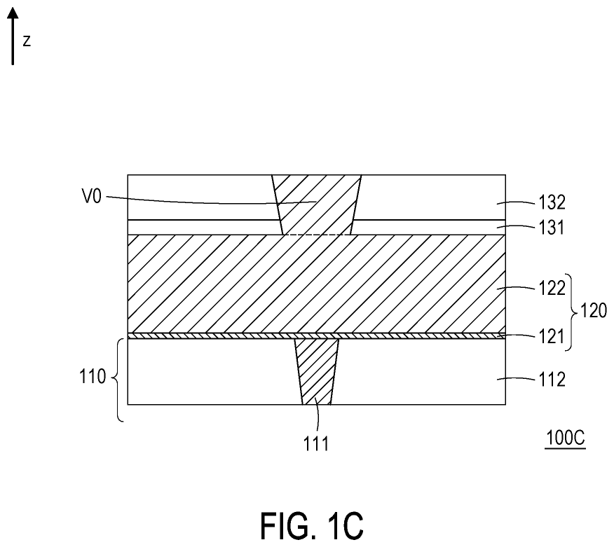

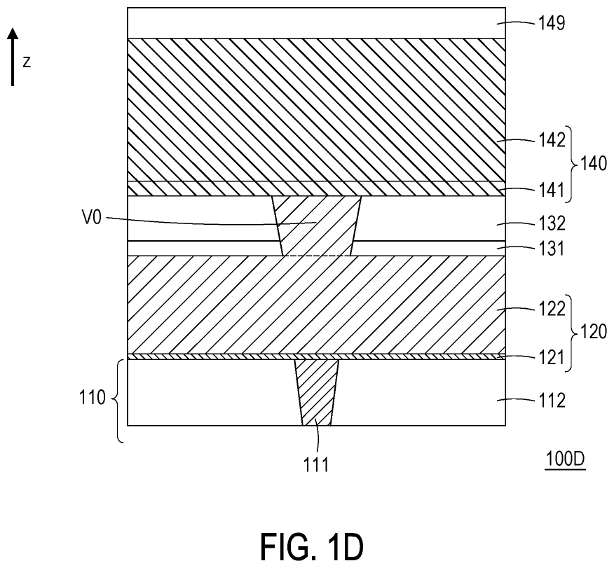

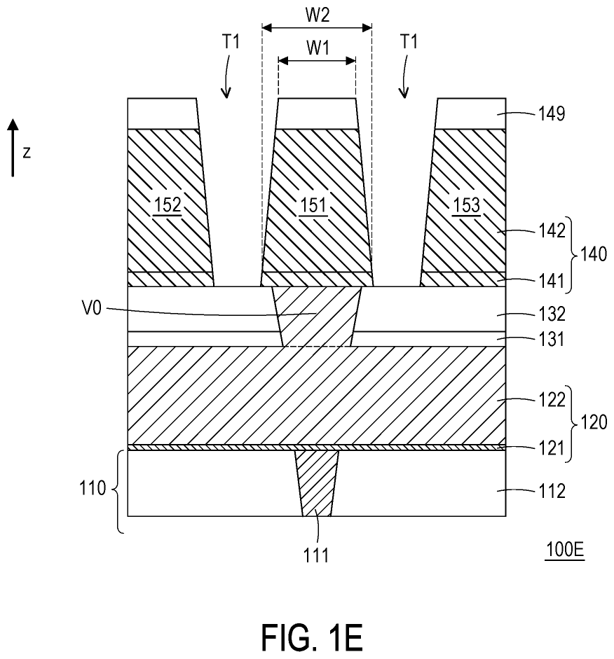

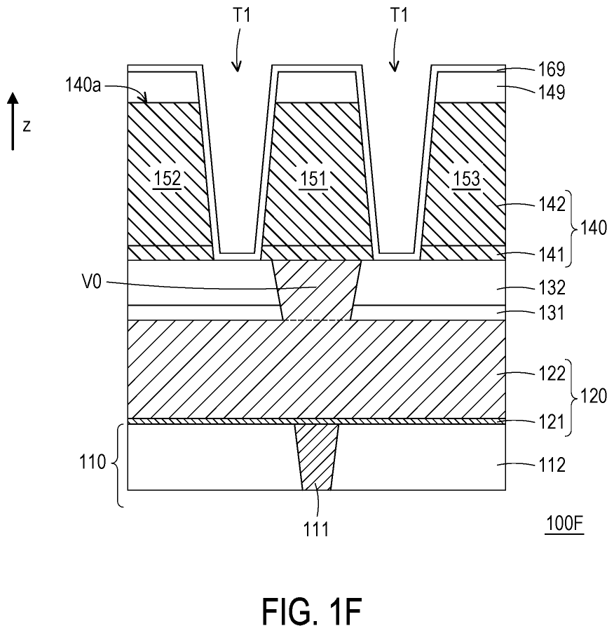

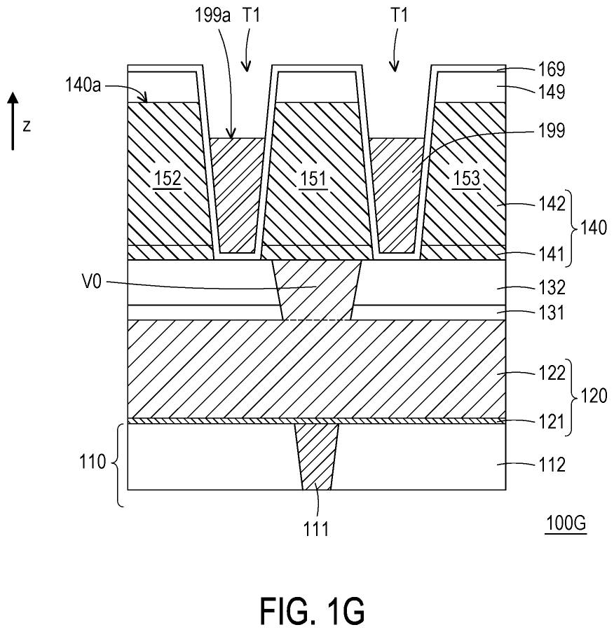

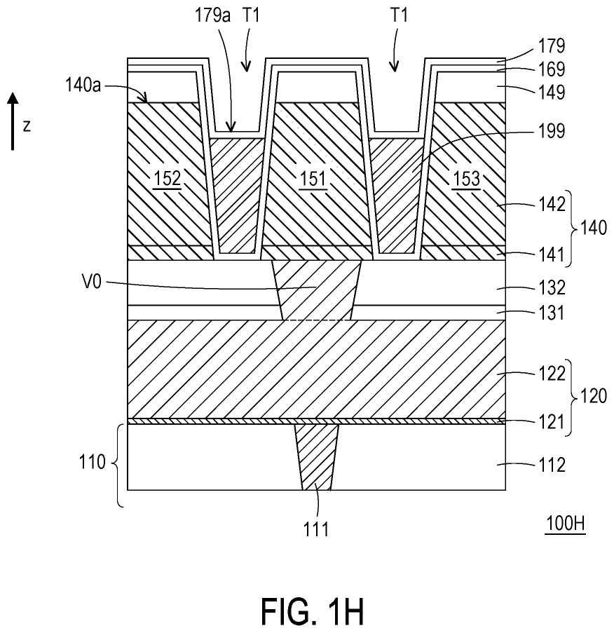

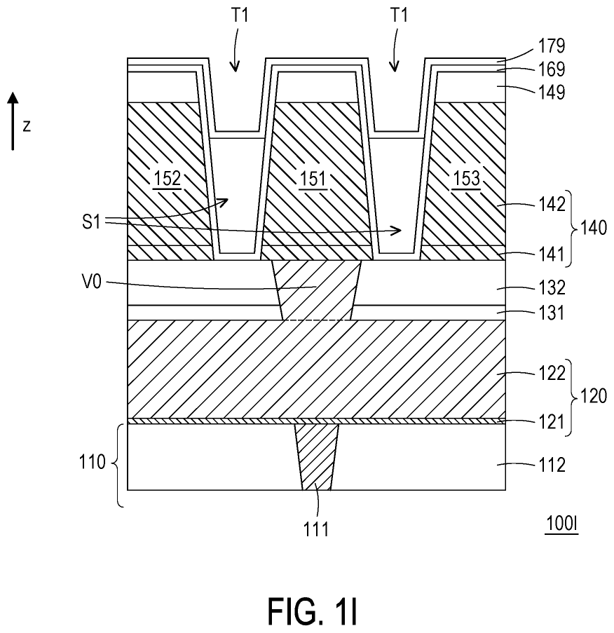

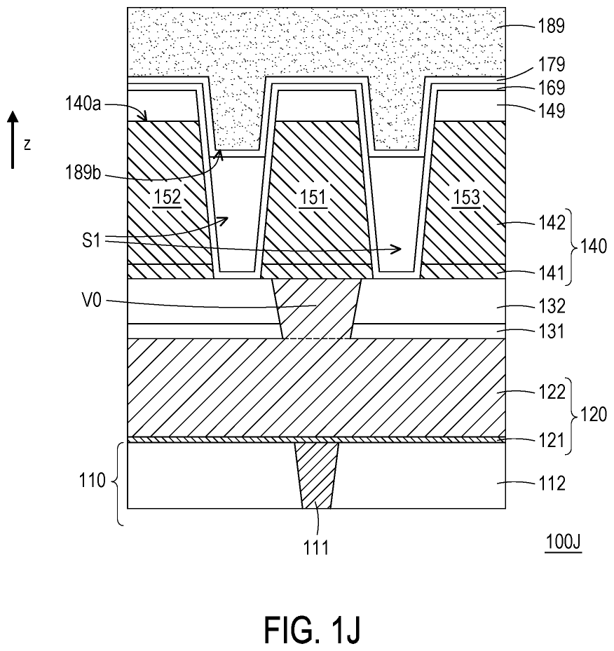

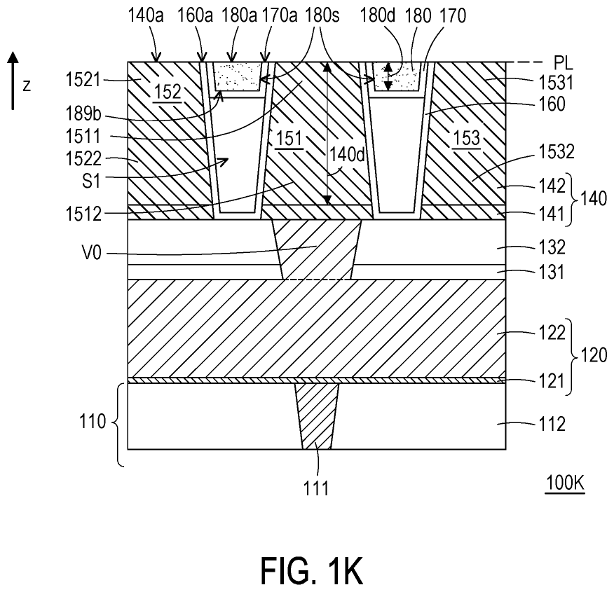

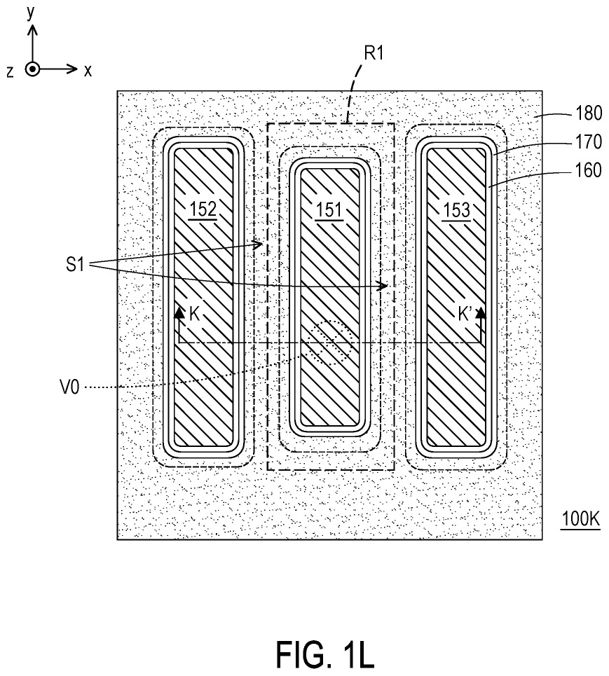

FIGS. 1A-1K illustrate various cross-sectional views of some embodiments of a method of forming an electronic device.

As shown in cross-sectional view of FIG. 1A, a structure 100A including a substrate 110 and a plurality of layers (e.g., layers 120, 131, 132, 139) or regions disposed on the substrate 100 or embedded in the substrate 110 is provided. The plurality of layers or regions may be formed by a suitable process such as low pressure chemical vapor deposition (LPCVD), plasma enhanced chemical vapor deposition (PECVD), high density chemical plasma vapor deposition (HDPCVD), atomic layer deposition (ALD), physical vapor deposition (PVD) or high density plasma chemical vapor deposition (HDPCVD), vapor transport deposition (VTD), ion implantation process, diffusion process, oxidation process, or the like. The plurality of layers or regions disposed on the substrate 110 or embedded in the substrate 110 may be considered a portion of the substrate 110. For example, the substrate 110 includes an insulating region 112 and a conductor 111 embedded in the insulating region 112. The conductor 111 may be a via electrically connected to a transistor. For example, the conductor 111 is electrically connected to an electrode (e.g., a gate electrode, a source electrode or a drain electrode) of a transistor.

The substrate 110 may include a semiconductor substrate (e.g., a silicon (Si) substrate or a semiconductor wafer), a printed circuit board (e.g., an FR-4 printed circuit board), or a glass substrate, and the disclosure is not limited thereto. A structure including a semiconductor substrate may be referred as a semiconductor structure. Take a semiconductor wafer as an example, the substrate includes a crystalline silicon wafer. The substrate 110 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 110 is made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. The substrate 110 may further include interconnect structure formed over and electrically connected to the various doped regions. The interconnect structure may include a circuitry fabricated by front end of line (FEOL) or middle end of line (MEOL) processes. For example, a conductive via may penetrate an insulating region and electrically connect to a gate electrode, a source region, or drain region.

The layers disposed on the substrate 110 include a conductive layer 120, insulating layers 131, 132, and a cap layer 139. For example, the conductive layer 120 may include a conductive layer 121 and a conductive layer 122 with the same or similar pattern, and may be referred to as a M0 layer. The M0 layer may include interconnects. The conductive layer 121 may be referred as a seed layer, a conductive glue layer, or a diffusion barrier. The conductive layer 122 may be referred as a plated layer. The insulating layer 131 may include an etching-stop layer (ESL). The insulating layer 132 may include a low-k dielectric layer. The cap layer 139 may include a hard-mask (HM) layer. A material of a hard-mask layer may include a conductive material (e.g., titanium nitride (TiN), tantalum nitride (TaN), or amorphous carbon), an insulating material (e.g., oxide or nitride), or a semiconductor material (e.g., amorphous silicon (a-Si)).

As shown in cross-sectional view of FIG. 1B, a structure 100B including at least on hole H0 is formed. The hole H0 is formed to penetrate through the layers 131, 132, 139 to expose a portion of the M0 layer 120. The hole H0 may be form by a suitable semiconductor process (e.g., a photolithography followed by an etching process).

As shown in cross-sectional view of FIG. 1C, a structure 100C including at least one conductive via V0 is formed. The conductive via V0 may be formed by filling conductive material into the hole H0 (as shown in FIG. 1B) through a suitable semiconductor process (e.g., a physical vapor deposition (PVD) and/or plating process). A top surface of the conductive via V0 and the top surface of the insulating layer 132 may be substantially coplanar, and the top surface of the conductive via V0 and the top surface of the insulating layer 132 may be treated by a planarization process (e.g., a chemical mechanical planarization (CMP) process). During the aforementioned planarization process, the cap layer 139 as shown in FIG. 1B is removed. During the aforementioned planarization process, a portion of the insulating layer 132 as shown in FIG. 1B may be further removed.

As shown in cross-sectional view of FIG. 1D, a structure 100D including at least one conductive layer is formed. Two conductive layers 141, 142 and one cap layer 149 are shown in FIG. 1D, and the disclosure is not limited thereto. The conductive layer 141 may be referred as a seed layer, a conductive glue layer, or a diffusion barrier. The conductive layer 142 may be referred as a plated layer. The cap layer 149 may include a hard-mask (HM) layer.

As shown in cross-sectional view of FIG. 1E, a structure 100E including at least one trench T1 is formed. Two trenches T1 that are not connected seemingly in a cross-sectional view may be connected essentially in other cross-sectional view. The trenches T1 are formed to penetrate through the conductive layers 141, 142 and the cap layer 149 disposed on the conductive layers 141 and 142. The trenches T1 may be form by a suitable semiconductor process (e.g., a photolithography followed by an etching process).

A plurality of conductive layers 141, 142 are referred as a conductive layer 140. That is, the conductive layer 140 may include a conductive layer 141 and a conductive layer 142 with similar pattern, and may be referred to as a M1 layer. After the trenches T1 are formed, interconnects 151, 152, 153 are formed in the patterned conductive layer 140, and the interconnects 151, 152, and 153 are electrically insulated from each other by the plurality of trenches T1. In a cross-sectional view, the top dimension (e.g., top width) of the trenches T1 may be greater than the bottom dimension (e.g., bottom width) of the trenches T1, and the top dimension (e.g., top width) of the interconnects 151, 152, and 153 may be less than the bottom dimension (e.g., bottom width) of the interconnect 151, 152, and 153. For example, the top width W1 of the interconnect 151 less than the bottom width W2 of the interconnect 151. In other word, in the cross-sectional view, a shape of the trenches T1 may be an inverted trapezoid, and a shape of the interconnects 151, 152, 153 may be a trapezoid. In subsequently performed processes, the trenches T1 having inverted trapezoid shape may improve the step coverage of the film layer which is formed on the trenches T1 and/or embedded in the trenches T1.

As shown in cross-sectional view of FIG. 1F, a structure 100F including an insulating layer 169 is formed. The insulating layer 169 may include a dielectric capping layer. The insulating layer 169 may be formed by a suitable process and conformally cover the resulted structure 100E illustrated in FIG. 1E. For example, the insulating layer 169 may be formed by a deposition process (e.g., chemical vapor deposition (CVD), atomic layer deposition (ALD), vapor transport deposition (VTD), or the like). For example, the insulating layer 169 may be formed by an exfoliation process (e.g., sonication, mechanical, hydrothermal, electrochemical, laser-assisted, and microwave-assisted exfoliation). A further process, such as a thermal process (e.g., heating, annealing, or the like), may be performed for forming the insulating layer.

A material of the insulating layer 169 may include silicon oxide (SiO), silicon carbide (SiC), silicon nitride (SiN), silicon oxynitride (SiNO), silicon carbon nitride (SiCN), nitride-doped silicon oxide (SiCON), aluminum nitride (AlN), aluminum oxynitride (AlON), aluminum oxide (AlO), or a 2D material. In an embodiment, the thickness of the insulating layer 169 is less than or substantially equal to 5 nanometers (nm). In an alternative embodiment, the thickness of the insulating layer 169 is about 2 angstroms (Å) to 50 Å.

As shown in the cross-sectional view of FIG. 1G, a structure 100G including a sacrificial layer 199 is formed. The sacrificial layer 199 may be formed by a deposition process and a recessing process (e.g., a partially removal process). The sacrificial layer 199 is disposed and/or filled at the bottom of the trenches T1, and the top surface 199a of the sacrificial layer 199 is lower than the top surface 140a of the conductive layer 140. In an embodiment, the thickness of the sacrificial layer 199 is less than or substantially equal to 150 Å. In an alternative embodiment, the thickness of the sacrificial layer 199 is about 10 Å to 100 Å. The sacrificial layer 199 will be removed to form an air gap during a subsequently performed process.

As shown in the cross-sectional view of FIG. 1H, a structure 100H including an insulating layer 179 is formed. The insulating layer 179 may include a sustaining layer. The insulating layer 179 may be formed by a deposition process and conformally cover a portion of the resulted structure 100G illustrated in FIG. 1G. The insulating layer 179 covers the top surfaces 199a of the sacrificial layer 199. The insulating layer 179 further covers portions of the insulating layer 169 which are not in contact with the sacrificial layer 199. The insulating layer 179 is spaced apart from the cap layer 149 and the interconnects 151, 152, 153 by the insulating layer 169. The sidewalls of the trenches T1 that are not covered by the sacrificial layer 199 are covered by the insulating layer 179. The top surface 179a of a bottommost portion of the insulating layer 179 is lower than the top surface 140a of the conductive layer 140.

A material of the insulating layer 179 may include silicon oxide (SiO), silicon carbon oxide (SiCO), silicon oxynitride (SiNO), silicon carbon nitride (SiCN), nitride-doped silicon oxide (SiCON). In an embodiment, the thickness of the insulating layer 179 is less than or substantially equal to 150 Å. In an alternative embodiment, the thickness of the insulating layer 179 is about 2 Å to 100 Å.

As shown in cross-sectional views of FIG. 1H to FIG. 1I, a removal process is performed. The removal process may be performed on the resulted structure 100H as shown in FIG. 1H. After performing the above-mentioned removal process, at least a portion of the sacrificial layer 199 is removed. As such, as shown in the cross-sectional view of FIG. 1I, a structure 100I including an air gap S1 disposed between two adjacent interconnects (e.g., between two interconnects 151 and 152 and two interconnects 151 and 153) is formed.

A material of the sacrificial layer 199 (as shown in FIG. 1H) may have an etch selectivity with respect to the insulation layer 169 and the insulation layer 179. A material of the sacrificial layer 199 may be or include oxide, nitride, or metal oxide, metal nitride, or organic material. For example, the materials of the insulation layer 169 and/or the insulation layer 179 include oxide, and the material of the sacrificial layer 199 may include metal nitride or nitride. For example, the materials of the insulation layer 169 and/or the insulation layer 179 include nitride, and the material of the sacrificial layer 199 may include oxide or metal nitride. For example, the material of the sacrificial layer 199 may include silicon oxide, silicon nitride, titanium nitride (TiN), lanthanum oxide (LaO), or aluminum oxide (Al₂O₃). In an embodiment where the material of the sacrificial layer 199 is titanium nitride, a removal process using an ammonia hydroxide-hydrogen peroxide-water mixture (APM) solution may be performed. In an embodiment where the material of the sacrificial layer 199 is lanthanum oxide, a removal process using a solvent containing hydrochloric acid (HCl) may be performed. In an embodiment where the material of the sacrificial layer 199 is aluminum oxide, a removal process using a solvent containing tetramethylammonium hydroxide (TMAH) may be performed. In an embodiment where the material of the sacrificial layer 199 is organic material, a removal process using an ashing process (e.g., a UV ashing process) or a heating process (e.g., a thermal baking process) may be performed.

It is noted that the disclosure retains the possibility that the sacrificial layer 199 is not completely removed. For example, the remaining slight sacrificial layer 199 may be disposed on a portion of the insulating layer 169 embedded in the trench T1. For example, the remaining slight sacrificial layer 199 may be disposed on the bottommost surface of a portion of the insulation layer 179 embedded in the trench T1. In an embodiment where the material of the sacrificial layer 199 is an insulating material, it will not have a significant impact on the conductivity of the interconnects 151, 152, 153 essentially. In an embodiment, a removal rate of the sacrificial layer 199 is higher than 80%. In an alternative embodiment, a removal rate of the sacrificial layer 199 is higher than 95%.

As shown in the cross-sectional view of FIG. 1J, a structure 100J including an insulating layer 189 is formed. The insulating layer 189 is formed to cover the insulating layer 179 and fill into the top portions of the trenches T1 (as shown in FIG. 1I). The bottommost surface 189b of the insulating layer 189 is lower than the top surface 140a of the conductive layer 140. The insulating layer 189 is spaced apart from the insulating layer 169 by the insulating layer 179. A material of the insulating layer 189 may include silicon oxycarbide (SiCOH) or a material having a good adhesion with other insulating layer 179.

It is noted that the sacrificial layer 199 (as shown in 1H) is removed before the insulating layer 189 being formed in the embodiment as shown in FIG. 1H to FIG. 1J, but the disclosure is not limited thereto. In an alternative embodiment, the sacrificial layer 199 may be removed after the insulating layer 189 being formed.

As shown in cross-sectional view of FIG. 1K, a structure 100K including insulating layers 160, 170, 180 is formed. As shown in FIG. 1J to FIG. 1K, the insulating layers 160, 170, 180 may be formed by removing portions of the insulating layers 169, 179, 189 by performing a suitable removal process (e.g., a planarization process). Additionally, during the aforementioned removal process, the cap layer 149 (as shown in FIG. 1J) is removed. The top surfaces (i.e., the top surfaces 140a) of the interconnects 151, 152, and 153 are exposed after performing the aforementioned removal process. The top surfaces 140a of the interconnects 151, 152, 153, the top surface 160a of the insulating layer 160, the top surface 170a of the insulating layer 170, and the top surface 170a of the insulating layer 170 may be substantially coplanar. A portion of the insulating layers 170, 180 are vertically spaced apart from a portion of the insulating layers 160, 132 by the air gap S1. The insulating layer 170 extends from a sidewall of the upper portion 1511 of the interconnect 151 to sidewalls of upper portion 1521, 1531 of the interconnects 152, 153. The insulating layer 160 extends from a sidewall of the interconnect 151 to sidewalls of the interconnect 152, 153, and the air gap S1 is enclosed by a portion of the insulating layer 160 and a portion of the insulating layer 170.

It is noted that the sacrificial layer 199 (as shown in 1H) is removed before the insulating layer 180 being formed in the embodiment as shown in FIG. 1H to FIG. 1K, but the disclosure is not limited thereto. In an alternative embodiment, the sacrificial layer 199 may be removed after the insulating layer 180 being formed.

The structure 100K as shown in FIG. 1K or the structure 100L as shown in FIG. 1L may be a portion of an electronic device. That is, FIG. 1K illustrates a various partially cross-sectional view of some embodiment of a method of forming an electronic device, and/or FIG. 1L illustrates a various partially top view of some embodiments of an electronic device. For example, FIG. 1K may be referred as a partial cross-sectional view corresponding to the K-K′ cutting line as shown in FIG. 1L of some embodiments of an electronic device; and/or, FIG. 1L may be referred as a top view corresponding to the plane PL as shown in FIG. 1K. As sown in FIGS. 1K and/or 1L, the electronic device may include a substrate 110, a plurality of interconnects 151, 152, 153 disposed on the substrate 110, an insulating layer 180 is disposed between two adjacent interconnects (e.g., between two interconnects 151 and 152 and two interconnects 151 and 153). An air gap S1 is formed between the insulating layer 180 and substrate 110. A lower portion 1512 of the interconnect 151 is laterally spaced apart from lower portions 1522, 1532 of the interconnects 152, 153 by the air gap S1. The insulating layer 180 is disposed laterally between an upper portion 1511 of the interconnect 151 and upper portions 1521, 1531 of the interconnects 152, 153. In an embodiment, in a top view, the ring-shaped air gap S1 surrounds at least one interconnect (e.g., the interconnect 151).

The air gap S1 may be referred as a space in which there may be no solid material. The gas pressure in the air gap S1 may be extremely low or close to vacuum. In an embodiment, the air gap S1 may reduce signal interference or coupling capacitance between two adjacent interconnects (e.g., between two interconnects 151 and 152 and two interconnects 151 and 153). As such, the electronic device may have better performance and/or quality.

The interconnect 151 is electrically connected to a device (e.g., a transistor) by one or more conductor (e.g., the conductive via 111). That is, the heat generated may be transferred to the interconnect 151 easily and quickly when the device is operating. One or more interconnects 152, 153 adjacent to the interconnect 151 may be electrically insulated from the interconnect 151. The interconnects 152, 153 may be referred as dummy patterns. It is noted that “dummy” here may be referred to the dummy on the signal, but may have other uses. For example, during the process of forming interconnects (e.g., interconnects 151, 152, 153), a dummy pattern may cause corresponding stress in a corresponding portion of the structure, thereby the process quality may be improved. For example, the interconnects 152, 153 may be electrically grounded, thereby the electromagnetic interference may be reduced. For example, the interconnects 152, 153 may be thermally coupled to a heat dispersion, thereby the heat dissipation efficiency may be improved.

The insulating layer 160 may be referred as a thermal boundary resistance (TBR) layer and the insulating layer 160 has better thermal conductivity. The thermal boundary resistance layer has high thermal conductivity and good electrical isolation and may be formed of SiN, AlN, SiO₂, silicon carbide (SiC), diamond or a suitable insulating 2D material (e.g., hexagonal boron nitride (h-BN, graphitic BN)) having properties of electrically insulating the interconnect 151 and allowing heat from the interconnect 151 to pass through the thermal boundary resistance layer. In an embodiment, the thermal conductivity of the material of the insulation layer 160 is higher than a thermal conductivity of the material of the interconnects 151, 152, 153 of the conductive layer 140 (e.g., the M1 layer). In an embodiment, the thickness of the insulating layer 160 is less than or substantially equal to 5 nanometers. In an alternative embodiment, the thickness of the insulating layer 160 is about 2 angstroms (Å) to 50 Å.

The thermal conductivity of the material of the insulating layer 180 may be higher than a thermal conductivity of the material of the interconnects 151, 152, 153 of the conductive layer 140 and may be referred as a thermal boundary resistance layer or a high thermal conductivity low k dielectric layer. The thermal conductivity of the insulating layer 180 may be two to ten times that of the interconnects 151, 152, 153. In an embodiment, a material of the insulating layer 180 may include AlN, h-BN, graphene oxide, diamond, SiC, or SiCN; and, a material of the interconnects 151, 152, 153 may include copper. Heat (e.g., thermal energy) in one interconnect (e.g., the interconnect 151) may be transferred to another interconnect (e.g., at least one of the interconnects 152, 153) through the insulating layer 180 quickly or efficiently.

Considering the interconnect 151 and the sidewall 180s of the insulating layer 180 corresponding or adjacent thereto, in the same unit and dimension, the multiplication of the side wall surface area and the thermal conductivity of the insulating layer 180 may be substantially equal to or greater than the multiplication of the side wall surface area and the thermal conductivity of the interconnect 151. In an embodiment, an equivalent thermal conductivity of the volume (which has an area R1 as shown in FIG. 1L with a thickness equal to the thickness 140d of the interconnect 151) is substantially equal to or greater than an equivalent thermal conductivity of a block which has a size equal to the volume and has a material the same to the interconnect 151, thereby the heat dissipation efficiency may be better.

Further considering a measurement method, the side wall surface area of the insulating layer 180 may be estimated by the multiplication of the thickness 180d and the inner contour length around the interconnect 151 of the insulating layer 180, and the side wall surface area of the interconnect 151 may be estimated by the multiplication of the thickness 140d and the outer contour length of the interconnect 151. Additionally, considering the totally thickness of the layer (e.g., the insulating layer 160 and the insulating layer 170) between interconnect 151 and insulating layer 180 being much less than the aforementioned contour lengths, the inner contour length of the insulating layer 180 is roughly equal to the outer contour length of the interconnect 151. As such, in the same unit and dimension, the multiplication of the thickness 180d and the thermal conductivity of the insulating layer 180 may be substantially equal to or greater than the multiplication of the thickness 140d and the thermal conductivity of the interconnect 151.

In an embodiment, the thickness 180d of the insulating layer 180 is less than or substantially equal to 100 nm. In an alternative embodiment, the thickness 180d of the insulating layer 180 is about 10 Å to 700 Å. In an alternative embodiment, the thickness 180d of the insulating layer 180 is about 10 Å to 400 Å.

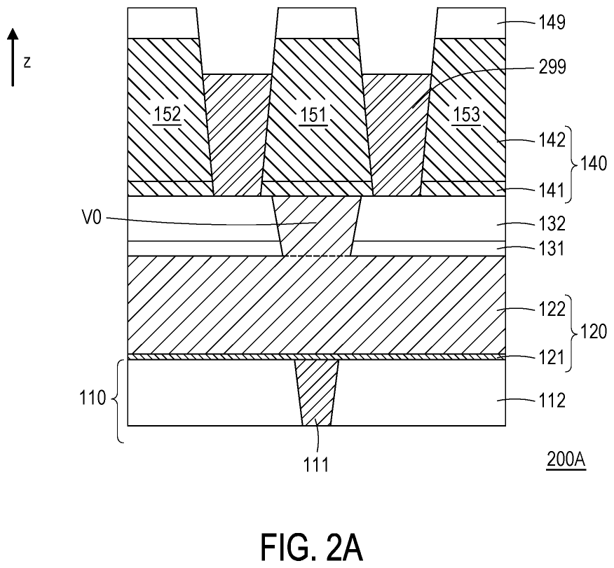

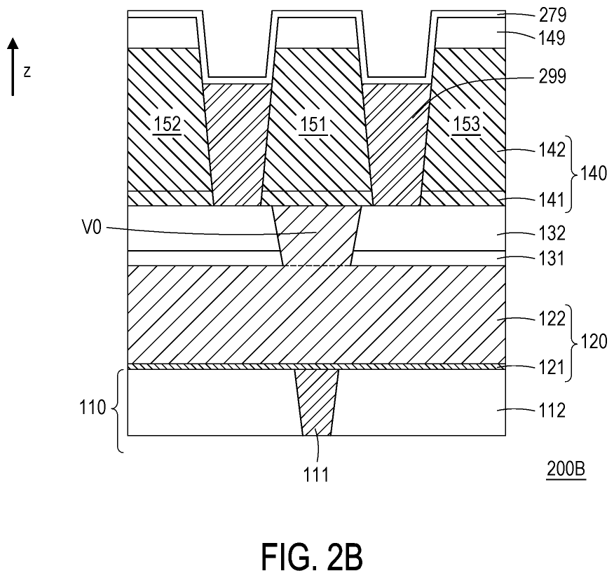

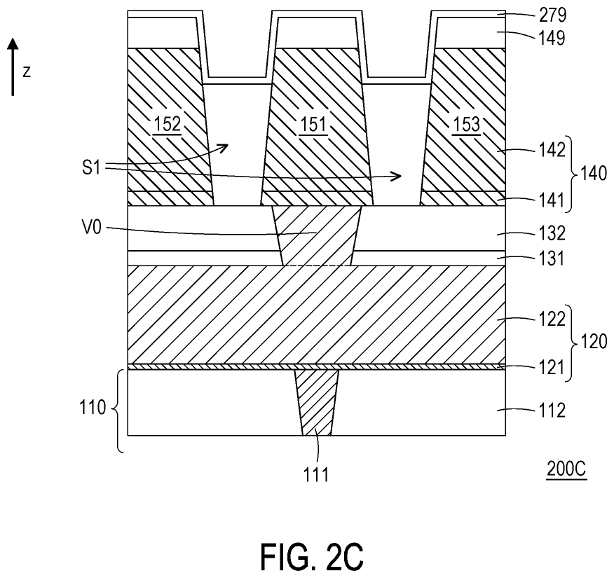

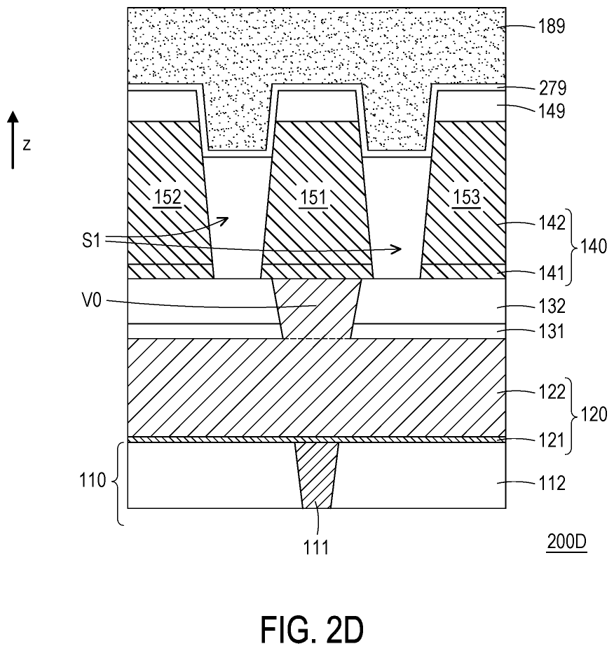

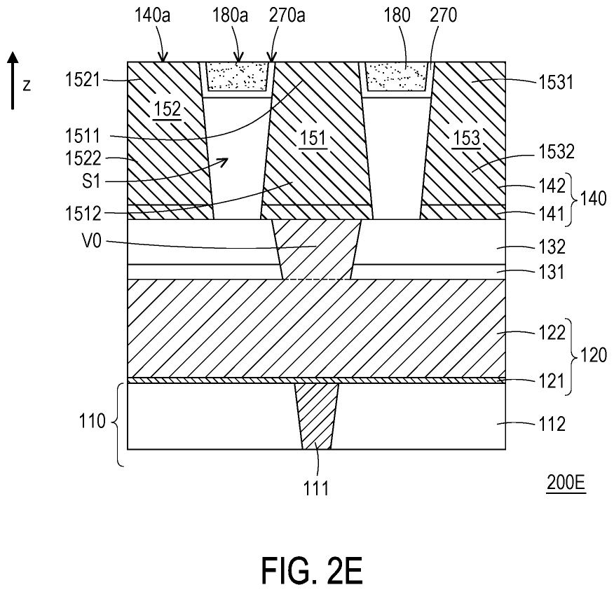

FIGS. 2A-2E illustrate various cross-sectional views of some embodiments of a method of forming an electronic device. In some embodiments, FIGS. 2A-2B may illustrate an exemplary method of forming an electronic device after the structure as shown in FIG. 1E.

As shown in cross-sectional view of FIG. 2A, a structure 200A including a sacrificial layer 299 is formed. The forming process and/or the material of the sacrificial layer 299 may be the same or similar to the forming process and/or the material of the sacrificial layer 199 as shown in FIG. 1G. The sacrificial layer 299 may be in contact with a lower portion of the side wall surface of the interconnects 151, 152, 153.

As shown in cross-sectional view of FIG. 2B, a structure 200B including an insulating layer 279 is formed. The forming process and/or the material of the insulating layer 279 may be the same or similar to the forming process and/or the material of the insulating layer 179 as shown in FIG. 1H.

As shown in cross-sectional views of FIG. 2B to FIG. 2C, a removal process is performed. The removal process may be performed on the structure 200B as shown in FIG. 2B, and the removal process may be performed the same or similar to the removal process as shown in FIG. 1H to FIG. 1I. After performing the above-mentioned removal process, at least a portion of the sacrificial layer 299 is removed. As such, as shown in cross-sectional view of FIG. 2C, a structure 200C including a air gap S1 disposed between two adjacent interconnects (e.g., between two interconnects 151 and 152 and two interconnects 151 and 153) is formed.

It is noted that the disclosure retains the possibility that the sacrificial layer 299 is not completely removed. For example, the remaining slight sacrificial layer 299 may be disposed on the interconnects 151, 152, 153 and/or the insulating layer 279.

As shown in cross-sectional view of FIG. 2D, a structure 200D including an insulating layer 189 is formed. The forming process and/or the material of the insulating layer 189 may be the same or similar to the forming process and/or the material of the insulating layer 189 as shown in FIG. 1J.

It is noted that the sacrificial layer 299 is removed before the insulating layer 189 being formed in the embodiment as shown in FIG. 2B to FIG. 2D, but the disclosure is not limited thereto. In an alternative embodiment, the sacrificial layer 299 may be removed after the insulating layer 189 being formed.

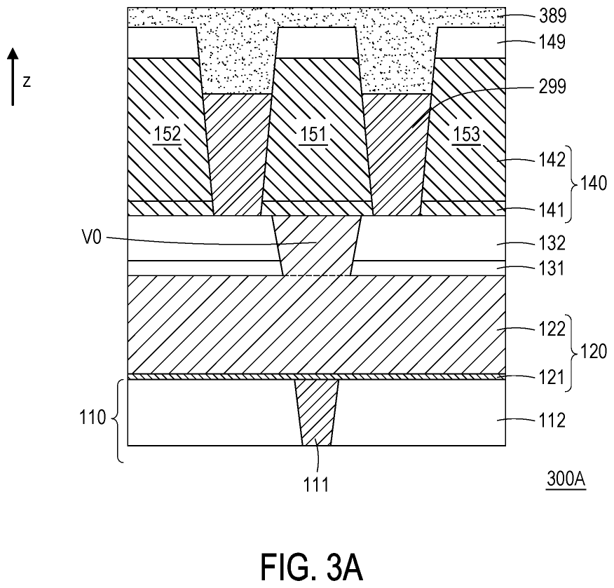

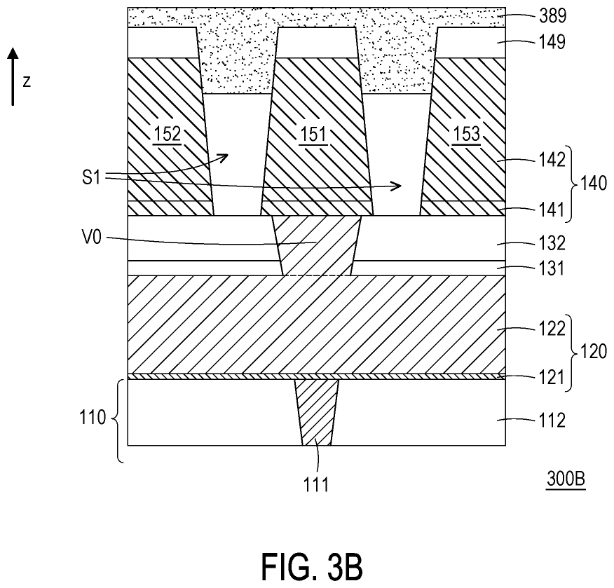

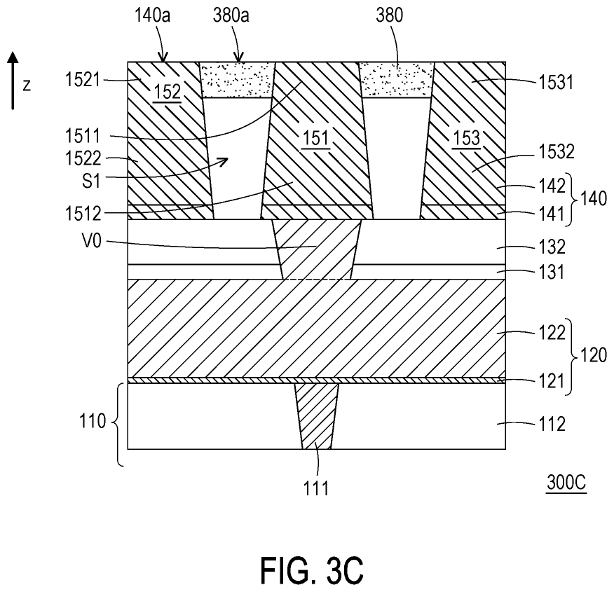

As shown in cross-sectional view of FIG. 2E, a structure 200E including insulating layers 270, 180 is formed. As shown in FIG. 2D to FIG. 3E, the insulating layers 270, 180 may be formed by removing a portion of the insulating layers 279, 189 respectively with performing a suitable removal process (e.g., a planarization process). Additionally, during the aforementioned removal process, the cap layer 149 (as shown in FIG. 2D) is removed. Interconnects 151, 152, 153 are exposed after performing the aforementioned removal process. Top surfaces 140a of the interconnects 151, 152, 153, a top surface 270a of the insulating layer 270, and a top surface 180a of the insulating layer 180 may be substantially coplanar. A portion of the insulating layers 270, 180 are vertically spaced apart from a portion of the insulating layer 132 by the air gap S1. The insulating layer 270 extends from a sidewall of the upper portion 1511 of the interconnect 151 to sidewalls of upper portion 1521, 1531 of the interconnects 152, 153, and the air gap S1 is enclosed by a portion of the insulating layer 132, a portion of the insulating 270 layer, and the interconnects 151, 152, 153.

It is noted that the sacrificial layer 299 is removed before the insulating layer 180 being formed in the embodiment as shown in FIG. 1B to FIG. 1E, but the disclosure is not limited thereto. In an alternative embodiment, the sacrificial layer 299 may be removed after the insulating layer 180 being formed.

The structure 200E as shown in FIG. 2E may be a portion of an electronic device. As shown in FIG. 2E, the electronic device may include a substrate 110, a plurality of interconnects 151, 152, 153 disposed on the substrate 110, an insulating layer 180 is disposed between two adjacent interconnects (e.g., between two interconnects 151 and 152 and two interconnects 151 and 153). An air gap S1 is formed between the insulating layer 180 and substrate 110. In an embodiment, in a top view, the air gap S1 surrounds at least one interconnect (e.g., the interconnect 151).

The electronic device as shown in FIG. 2E may be similar to the electronic device as shown in FIG. 1K, except that the electronic device as shown in FIG. 2E does not include the insulating layer 160 as shown in FIG. 1K. Additionally, a various partially top view of the electronic device as shown in FIG. 2E may be similar to the top view as shown in FIG. 1K. As shown in FIG. 2E, the insulating layer 270 may be in contact with an upper portion of the side wall surface of the interconnects 151, 152, 153.

FIGS. 3A-3C illustrate various cross-sectional views of some embodiments of a method of forming an electronic device. In some embodiments, FIGS. 3A-3C may illustrate an exemplary method of forming an electronic device after the structure as shown in FIG. 2A.

As shown in cross-sectional view of FIG. 3A, a structure 300A including an insulating layer 389 is formed. The forming process and/or the material of the insulating layer 389 may be the same or similar to the forming process and/or the material of the insulating layer 189 as shown in FIG. 2D. The insulating layer 389 may be in contact with a top surface of the sacrificial layer 299 and an upper portion of the side wall surface of the interconnects 151, 152, 153.

As shown in cross-sectional views of FIG. 3A to FIG. 3B, a removal process is performed. The removal process may be performed on the structure 300A as shown in FIG. 3A, and the removal process may be performed the same or similar to the removal process as shown in FIG. 1H to FIG. 1I or FIG. 2B to FIG. 2C. As such, as shown in cross-sectional view of FIG. 3B, a structure 300B including an air gap S1 disposed between two adjacent interconnects (e.g., between two interconnects 151 and 152 and two interconnects 151 and 153) is formed. A portion of the insulating layer 380 is vertically spaced apart from a portion of the insulating layer 132 by the air gap S1, and the air gap S1 is enclosed by a portion of the insulating layer 132, a portion of the insulating layer 380, and the interconnects 151, 152, 153.

It is noted that the disclosure retains the possibility that the sacrificial layer 299 is not completely removed. For example, the remaining slight sacrificial layer 299 may be disposed on the interconnects 151, 152, 153 and/or the insulating layer 389.

As shown in cross-sectional view of FIG. 3C, a structure 300C including an insulating layer 380 is formed. As shown in FIG. 3B to FIG. 3C, the insulating layer 380 may be formed by removing a portion of the insulating layer 389 with performing a suitable removal process (e.g., a planarization process). Additionally, during the aforementioned removal process, the temporary layer 149 (as shown in FIG. 3B) is removed. Interconnects 151, 152, 153 are exposed after performing the aforementioned removal process. Top surfaces 140a of the interconnects 151, 152, 153, and a top surface 380a of the insulating layer 380 may be substantially coplanar.

The structure 300C as shown in FIG. 3C may be a portion of an electronic device. As shown in FIG. 3C, the electronic device may include a substrate 110, a plurality of interconnects disposed on the substrate 110, an insulating layer 380 is disposed between two adjacent interconnects (e.g., between two interconnects 151 and 152 and two interconnects 151 and 153). An air gap S1 is formed between the insulating layer 380 and substrate 110. The insulating layer 380 is disposed laterally between an upper portion 1511 of the interconnect 151 and upper portions 1521, 1531 of the interconnects 152, 153. In an embodiment, in a top view, the air gap S1 surrounds at least one interconnect (e.g., the interconnect 151).

The electronic device as shown in FIG. 3C may be similar to the electronic device as shown in FIG. 2E and/or the electronic device as shown in FIG. 1K, except that the electronic device as shown in FIG. 3C does not include the insulating layer as shown in FIG. 2E. Additionally, a various partially top view of the electronic device as shown in FIG. 3C may be similar to the top view as shown in FIG. 1K. As shown in FIG. 3C, the insulating layer 380 may be in contact with an upper portion of the side wall surface of the interconnects 151, 152, 153.

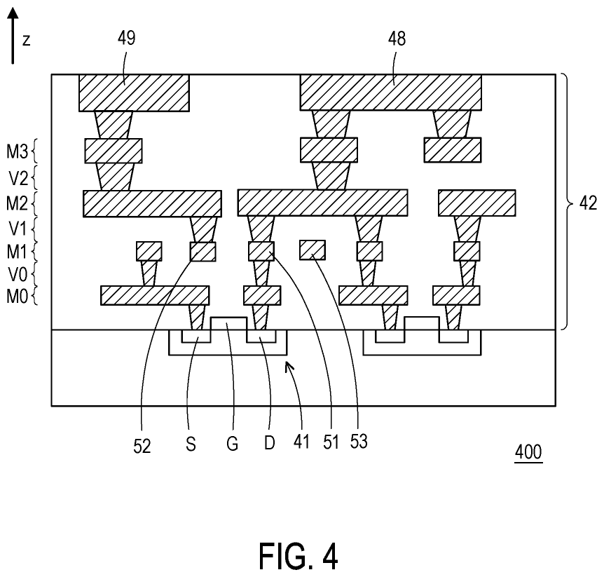

FIG. 4 illustrate an exemplary cross-sectional view of a die (e.g., a kind of electronic device) 400. The die 400 may include a substrate, an active device (e.g., a transistor), a passive device (e.g., a resistor, a capacitor, or an inductance), and/or an interconnect structure. The device may be formed using front-end of line (FEOL) fabrication techniques. The interconnect structure may be formed using back-end of line (BEOL) fabrication techniques and may be electrically coupled to a corresponding device. The die 400 as shown in FIG. 4 exemplarily illustrate a corresponding active device 41 and a corresponding interconnect structure 42. The die 400 may be a dynamic random access memory (DRAM) die, a static random access memory (SRAM) die or a high bandwidth memory (HBM) die, an application-specific integrated circuit (ASIC) die, an application processor (AP) die, a system on chip (SoC) die or a high performance computing (HPC) die, but the disclosure is not limited thereto. The active device 41 and/or the interconnect structure 42 are exemplary shown in FIG. 4, the formations or types of the active device 41 and/or the interconnect structure 42 are not limited in the disclosure.

The interconnect structure 42 may include a plurality interconnect layers (e.g., an M0 layer, an M1 layer, . . . or an Mn layer). Each interconnect layer may include corresponding interconnects. Corresponding interconnects in adjacent interconnect layers are electrically connected through corresponding conductive vias in the via layer (e.g., a V1 layer, a V2 layer, . . . or a Vn−1 layer) therebetween. A material of the M0 layer, the V1 layer, and/or the M1 layer may include Copper (Cu), Cobalt (Co), Ruthenium (Ru), Molybdenum (Mo), Chromium (Cr), Tungsten (W), Manganese (Mn), Rhodium (Rh), Iridium (Ir), Nickel (Ni), Palladium (Pd), Platinum (Pt), Silver (Ag), Gold (Au), Aluminum (Al). A thickness of the M0 layer, the V1 layer, and/or the M1 layer may about 50 Å to 500 Å. A material of the conductive glue layer (e.g., the conductive layer 121) may include Tantalum (Ta), Titanium (Ti) or other metal nitride (e.g., titanium nitride (TiN), tantalum nitride (TaN)). A thickness of the conductive glue layer may about 2 Å to 100 Å.

The topmost interconnect layer in the interconnect structure 42 may include a plurality of die pads. For example, the die pad 48 may be a signal pad (e.g., an I/O pad), and the die pad 48 may be a ground pad. A corresponding interconnect in the bottommost interconnect layer (e.g., the M0 layer) in the interconnect structure 42 is electrically connected a corresponding region of the device (e.g., the source S, the drain D, or the gate G, but the disclosure is not limited thereto) by one or more conductor (e.g., a conductive via).

Referring to FIG. 4 and the aforementioned figures, the structures 100K, 200E, 300C of the aforementioned embodiments may be a portion of the die 400. For example, the interconnects 51, 52, 53 as shown in FIG. 4 may be the same or similar to the interconnects 151, 152, 153 respectively as shown in FIGS. 1K, 2E and/or 3C. Additionally, for simplicity of illustration, a corresponding air gap S1 or insulating layers (e.g., the insulating layers 180, 380) are omitted in the FIG. 4.

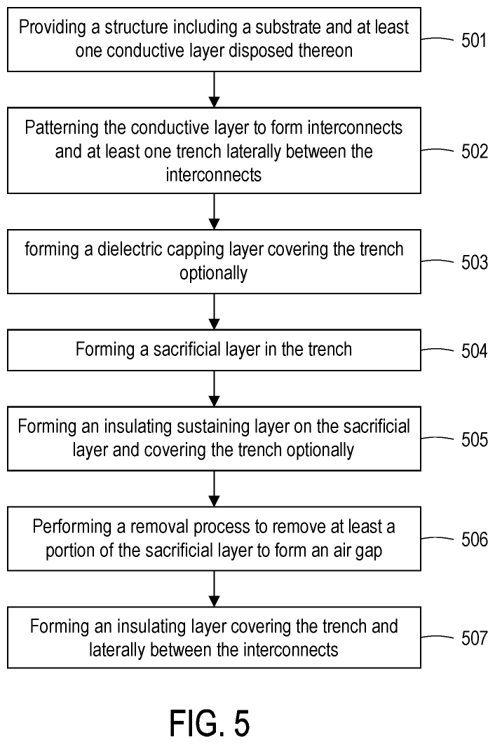

FIG. 5 illustrates a flow diagram of some embodiments of a method of forming an electronic device.

At act 501, a structure including a substrate and at least one conductive layer disposed on the substrate is provided. FIG. 1D illustrates a cross-sectional view corresponding to various embodiments of act 501. Optionally, a plurality of patterned or nonpatterned layers or regions are disposed on the substrate or embedded in the substrate.

At act 502, the conductive layer is patterned to form interconnects and at least one trench laterally between the interconnects. FIG. 1E illustrates a cross-sectional view corresponding to various embodiments of act 502. Optionally, in the cross-sectional view, a shape of the trench is the same or similar to an inverted trapezoid or an inverted triangle, and a shape of the interconnects is the same or similar to a trapezoid.

At act 503, optionally, a dielectric capping layer is formed covering the trench. FIG. 1F illustrates a cross-sectional view corresponding to various embodiments of act 503.

At act 504, a sacrificial layer is formed in the trench. The top surface of the sacrificial layer is lower than the top surface of the conductive layer. FIG. 1G, 2A or 3A illustrate a cross-sectional view corresponding to various embodiments of act 504.

At act 505, optionally, an insulating sustaining layer is formed on the sacrificial layer and covering the trench. FIG. 1H or 2B illustrate a cross-sectional view corresponding to various embodiments of act 505.

At act 506, at least a portion of the sacrificial layer is removed to form an air gap by a removal process. FIG. 1I, 2C or 3B illustrate a cross-sectional view corresponding to various embodiments of act 506.

At act 507, an insulating layer covering the trench and laterally between the interconnects is formed. FIG. 1J, 1K, 2D, 2E, 3A, 3B, or 3C illustrate a cross-sectional view corresponding to various embodiments of act 507. Top surfaces of the interconnects and the top surface of the insulating layer may be substantially coplanar as shown in FIG. 1K, 2E or 3C.

The sacrificial layer may be removed before forming the insulating layer covering the trench, as shown in FIG. 1I-1K, 2C-2E, or 3B-3C. The insulating layer covering the trench may be formed before removing the sacrificial layer, as shown in FIGS. 3A-3C.

Accordingly, in some embodiments, the present disclosure relates to an electronic device including at least one interconnect, a space, and an insulating layer. The insulating layer is disposed on the space. The insulating layer and/or the space surround the at least one interconnect, or the insulating layer and/or the space are disposed between two adjacent interconnects. The electronic device may have a better electrical performance and/or heat dissipation.

In accordance with some embodiments of the present disclosure, an electronic device includes a first interconnect, a second interconnect, and an insulating layer. A lower portion of the first interconnect is laterally spaced apart from a lower portion of the second interconnect by an air gap. The insulating layer is disposed laterally between an upper portion of the first interconnect and an upper portion of the second interconnect. In an embodiment, a top dimension of the first interconnect is less than a bottom dimension of the first interconnect. In an embodiment, a top surface of the insulating layer and a top surface of the first interconnect are substantially coplanar, and a thickness of the insulating layer is thinner than a thickness of the first interconnect. In an embodiment, a thermal conductivity of the insulating layer is higher than a thermal conductivity of the first interconnect and the second interconnect, and the insulating layer is thermally coupled to the first interconnect and the second interconnect. In an embodiment, a multiplication of a thickness and the thermal conductivity of the insulating layer is substantially equal to or greater than a multiplication of a thickness and the thermal conductivity of each of the first interconnect. In an embodiment, the first interconnect and the second interconnect are substantially identical in thickness. In an embodiment, the electronic device further includes an insulating sustaining layer extending from a sidewall of the upper portion of the first interconnect to a sidewall of the upper portion of the second interconnect. In an embodiment, the electronic device further includes a dielectric capping layer extending from a sidewall of the first interconnect to a sidewall of the second interconnect, wherein the air gap is enclosed by a portion of the insulating sustaining layer and a portion of the dielectric capping layer. In an embodiment, a thermal conductivity of the dielectric capping layer is higher than a thermal conductivity of the first interconnect and the second interconnect, and the dielectric capping layer is thermal coupled to the first interconnect, the insulating layer and the second interconnect. In an embodiment, the electronic device further includes an active device, wherein the first interconnect is electrically connected and thermal coupled to the active device. In an embodiment, the first interconnect and the active device are structurally overlapped. In an embodiment, the second interconnect is electrically insulated from the first interconnect. In an embodiment, the second interconnect is a dummy pattern.

In accordance with some embodiments of the present disclosure, an electronic device includes a substrate, an interconnect, a first insulating layer, and a second insulating layer. The interconnect is disposed on the substrate. The first insulating layer is disposed on the substrate. The second insulating layer is disposed over the first insulating layer and surrounding the interconnect. A portion of the first insulating layer is vertically spaced apart from a portion of the second insulating layer by an air gap. In an embodiment, a thermal conductivity of the second insulating layer is higher than a thermal conductivity of the interconnect, and the second insulating layer is thermal coupled to the interconnect. In an embodiment, a multiplication of a thickness and the thermal conductivity of the second insulating layer is substantially equal to or greater than a multiplication of a thickness and the thermal conductivity of the interconnect. In an embodiment, the electronic device further includes an active device disposed on the substrate, wherein the interconnect is electrically connected and thermal coupled to the active device, and the interconnect and the active device are structurally overlapped.

In accordance with some embodiments of the present disclosure, a method includes: providing a structure including a substrate and at least one conductive layer disposed on the substrate; patterning the conductive layer to form interconnects and at least one trench laterally between the interconnects; forming a sacrificial layer in the at least one trench; forming a first insulating layer covering the at least one trench; and performing a removal process to remove at least a portion of the sacrificial layer and to form an air gap. In an embodiment, the first insulating layer comprises an insulating sustaining layer disposed on the interconnects and the sacrificial layer, the method further includes: forming a second insulating layer disposed on the first insulating layer and laterally between the interconnects. In an embodiment, a thermal conductivity of the first insulating layer is higher than a thermal conductivity of the interconnects.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a first interconnect;
a second interconnect, wherein a lower portion of the first interconnect is laterally spaced apart from a lower portion of the second interconnect by an air gap; and
an insulating layer, disposed laterally between an upper portion of the first interconnect and an upper portion of the second interconnect.

2. The electronic device of claim 1, wherein a top dimension of the first interconnect is less than a bottom dimension of the first interconnect.

3. The electronic device of claim 1, wherein a top surface of the insulating layer and a top surface of the first interconnect are substantially coplanar, and a thickness of the insulating layer is thinner than a thickness of the first interconnect.

4. The electronic device of claim 1, wherein a thermal conductivity of the insulating layer is higher than a thermal conductivity of the first interconnect and the second interconnect, and the insulating layer is thermally coupled to the first interconnect and the second interconnect.

5. The electronic device of claim 4, wherein a multiplication of a thickness and the thermal conductivity of the insulating layer is substantially equal to or greater than a multiplication of a thickness and the thermal conductivity of each of the first interconnect.

6. The electronic device of claim 1, wherein the first interconnect and the second interconnect are substantially identical in thickness.

7. The electronic device of claim 1, further comprising:
an insulating sustaining layer, extending from a sidewall of the upper portion of the first interconnect to a sidewall of the upper portion of the second interconnect.

8. The electronic device of claim 7, further comprising:
a dielectric capping layer, extending from a sidewall of the first interconnect to a sidewall of the second interconnect, wherein the air gap is enclosed by a portion of the insulating sustaining layer and a portion of the dielectric capping layer.

9. The electronic device of claim 8, wherein a thermal conductivity of the dielectric capping layer is higher than a thermal conductivity of the first interconnect and the second interconnect, and the dielectric capping layer is thermal coupled to the first interconnect, the insulating layer and the second interconnect.

10. The electronic device of claim 1, further comprising:
an active device, wherein the first interconnect is electrically connected and thermal coupled to the active device.

11. The electronic device of claim 10, wherein the first interconnect and the active device are structurally overlapped.

12. The electronic device of claim 10, wherein the second interconnect is electrically insulated from the first interconnect.

13. The electronic device of claim 12, wherein the second interconnect is a dummy pattern.

14. An electronic device, comprising:
a substrate;
an interconnect, disposed on the substrate;
a first insulating layer, disposed on the substrate; and
a second insulating layer, disposed over the first insulating layer and surrounding the interconnect;
wherein a portion of the first insulating layer is vertically spaced apart from a portion of the second insulating layer by an air gap.

15. The electronic device of claim 14, wherein a thermal conductivity of the second insulating layer is higher than a thermal conductivity of the interconnect, and the second insulating layer is thermal coupled to the interconnect.

16. The electronic device of claim 15, wherein a multiplication of a thickness and the thermal conductivity of the second insulating layer is substantially equal to or greater than a multiplication of a thickness and the thermal conductivity of the interconnect.

17. The electronic device of claim 14, further comprising:
an active device, disposed on the substrate, wherein the interconnect is electrically connected and thermal coupled to the active device, and the interconnect and the active device are structurally overlapped.

18. A method, comprising:
providing a structure including a substrate and at least one conductive layer disposed on the substrate;
patterning the conductive layer to form interconnects and at least one trench laterally between the interconnects;
forming a sacrificial layer in the at least one trench;
forming a first insulating layer covering the at least one trench; and
performing a removal process to remove at least a portion of the sacrificial layer and to form an air gap.

19. The method of claim 18, wherein the first insulating layer comprises an insulating sustaining layer disposed on the interconnects and the sacrificial layer, the method further comprising:
forming a second insulating layer disposed on the first insulating layer and laterally between the interconnects.

20. The method of claim 18, wherein a thermal conductivity of the first insulating layer is higher than a thermal conductivity of the interconnects.
